(19) United States
(12) Patent Application Publication
(10) Pub. No.: US 2025/0029853 A1
(43) Pub. Date: Jan. 23, 2025

(54) DETERMINING SUBSTRATE DECENTERING IN SEMICONDUCTOR PROCESSING SYSTEMS EMPLOYED TO DEPOSIT MATERIAL LAYERS ONTO SUBSTRATES

(71) Applicant: ASM IP Holding B.V., Almere (NL)

(72) Inventor: Christopher Cillie, Scottsdale, AZ (US)

(21) Appl. No.: 18/775,963

(22) Filed: Jul. 17, 2024

Related U.S. Application Data
(60) Provisional application No. 63/514,246, filed on Jul. 18, 2023.

(51) Int. Cl. H01L 21/67; G01J 5/48; H01L 21/66

(52) U.S. Cl. CPC H01L 21/67259; G01J 5/48; H01L 21/67248; H01L 22/12

(57) ABSTRACT

A semiconductor processing system includes a chamber body, a substrate support, a pyrometer, and a controller. The substrate support is arranged within an interior of the chamber body and is supported for rotation about a rotation axis. The pyrometer is supported above the chamber body, is radially offset from the rotation axis, and is optically coupled to the interior of the chamber body. The controller is operably connected to the substrate support and is disposed in communication with the pyrometer. The controller is further responsive to instructions recorded on a non-transitory machine-readable memory to seat a substrate on the substrate support, acquire a temperature measurement acquired using electromagnetic radiation emitted by the substrate, and determine decentering of the substrate relative to the rotation axis using the electromagnetic radiation received at the pyrometer. Material layer deposition methods and computer program products are also described.

### CROSS-REFERENCE TO RELATED APPLICATION(S)

This application claims the benefit of U.S. Provisional Application 63/514,246 filed on Jul. 18, 2023, the entire contents of which are incorporated herein by reference.

### FIELD OF INVENTION

The present disclosure generally relates to depositing material layers onto substrates. More particularly, the present disclosure relates to determining decentering of substrates on substrate supports during the deposition of material layers on substrates, such as material layers deposited onto substrates during the fabrication of semiconductor devices.

### BACKGROUND OF THE DISCLOSURE

Material layers are commonly deposited onto substrates during the fabrication of semiconductor devices, such as during the fabrication of integrated circuits and power electronic semiconductor devices. Material layer deposition is generally accomplished by seating the substrate within a reactor on a substrate support, heating the substrate to a desired material layer deposition temperature, and exposing the substrate to one or more material layer precursors such that a material layer forms on the substrate under environmental conditions selected to cause a material layer to deposit onto the substrate. Once the material layer reaches a desired thickness, the flow of material layer precursors ceases and the substrate is unseated from the substrate support so that the substrate may be sent on for further processing, as appropriate for the material layer being deposited onto the substrate. Seating and unseating of the substrate may be accomplished using lift pins, which are typically slidably received within the substrate support and movable between a recessed position, whereat the lift pins dangle from the substrate support, and an extended position, whereat the lift pins protrude above the substrate support.

In some material layer deposition processes properties of the material layer may be influenced by positioning of the substrate on the substrate support. For example, decentered seating of the substrate may introduce cross-substrate variation into the material layer deposited onto the substrate, such as in material layer thickness variation and/or concentration of dopant or alloying constituents. Decentering may also introduce variation into substrate position on the transfer robot end effector employed to unload the substrate from the reaction chamber employed to deposit the material layer onto the substrate. And decentering may, in some deposition processes, potentially lead to damage to the substrate itself and/or the reaction chamber employed for deposition of the material layer, such as when the decentering is such that the substrate enters a movement envelope of the transfer robot end effector.

Various countermeasures exist to control the position of substrates on substrate supports in semiconductor processing systems. For example, imaging devices can be employed to acquire image data suitable to determine accuracy of placement of a substrate on the substrate support. Load cells may be employed to monitor differences between an expected center of gravity and actual center of gravity of a substrate while supported within the semiconductor processing system, such as when the substrate is carried by lift pins between the transfer robot end effector and the substrate support. And automatic wafer centering sensors, e.g., AWC sensors, may be employed to monitor placement of the substrate on the transfer robot end effector during substrate unloading to discern change in substrate positioning in the semiconductor processing during sequential deposition events.

Such methods and systems have generally been considered suitable for their intended purpose. However, there remains a need in the art for improved semiconductor processing systems, material layer deposition methods, and computer program products for determining substrate centering in semiconductor processing systems employed to deposit material layers onto substrates. The present disclosure provides a solution to this need.

### SUMMARY OF THE DISCLOSURE

A semiconductor processing system is provided. The semiconductor processing system includes a chamber body, a substrate support, a pyrometer, and a controller. The substrate support is arranged within an interior of the chamber body and is supported for rotation about a rotation axis. The pyrometer is supported above the chamber body, is radially offset from the rotation axis, and is optically coupled to the interior of the chamber body. The controller is operably connected to the substrate support and is disposed in communication with the pyrometer. The controller is further responsive to instructions recorded on a non-transitory machine-readable memory to seat a substrate on the substrate support, acquire a temperature measurement acquired using electromagnetic radiation emitted by the substrate, and determine decentering of the substrate relative to the rotation axis using the electromagnetic radiation received at the pyrometer.

In addition to one or more of the features described above, or as an alternative, further examples of the system may include that the pyrometer is radially offset from the rotation axis by between about 135 millimeters and about 150 millimeters. The pyrometer may have a field of view with a width that is between about 2 millimeter and about 10 millimeters at the surface of the substrate.

In addition to one or more of the features described above, or as an alternative, further examples of the system may include that the substrate has a radially outer bevel surface portion and a radially inner interior surface portion. The rotation axis may intersect the interior surface portion of the substrate. The peripheral surface portion of the substrate may extend about the interior surface portion of the substrate, the bevel surface portion may extend circumferentially about the peripheral surface portion of the substrate, and an optical axis of the pyrometer may intersect at least one of peripheral surface portion and the bevel surface portion of the substrate.

In addition to one or more of the features described above, or as an alternative, further examples of the system may include that the instructions cause the controller to rotate the substrate support about the rotation axis, acquire a first temperature measurement using electromagnetic radiation emitted by the substrate at a first rotary position, and acquire a second temperature measurement using electromagnetic radiation emitted by the substrate at a second rotary position. A difference may be calculated between the first temperature measurement and a second temperature measurement. The calculated difference may be compared to a predetermined temperature difference value to determine decentering of the substrate.

In addition to one or more of the features described above, or as an alternative, further examples of the system may include that the instructions cause the controller to acquire a plurality of temperature measurements using electromagnetic radiation emitted by the substrate and received at the pyrometer during rotation of the substrate and substrate support about the rotation axis, and calculate a standard deviation of the plurality of temperature measurements. The calculated standard deviation may be compared to a predetermined temperature standard deviation value to determine decentering of the substrate.

In addition to one or more of the features described above, or as an alternative, further examples of the system may include that the instructions further cause the controller to acquire a plurality of temperature measurements using electromagnetic radiation emitted by the substrate and received at the pyrometer during rotation of the substrate and the substrate support about the rotation axis and determine amplitude of temperature measurement oscillation at a frequency twice a rotational speed of the substrate support. The determined amplitude of temperature measurement oscillation may be compared to a predetermined temperature measurement oscillation value to determine decentering of the substrate.

In addition to one or more of the features described above, or as an alternative, further examples of the system may include that the pyrometer is a first pyrometer and that the semiconductor processing system further includes one or more second pyrometer. The one or more second pyrometer may be supported above the chamber body. The one or more second pyrometer may radially inward of the first pyrometer. The one or more pyrometer may be radially between the rotation axis and the first pyrometer. The one or more second pyrometer may be circumferentially offset from the first pyrometer about the rotation axis.

In addition to one or more the features described above, or as an alternative, further examples of the system may include that the first pyrometer is arranged along a first optical axis, that the second pyrometer is arranged along a second optical axis, and that the second optical axis is radially between the first optical axis and the rotation axis. The second optical axis may be circumferentially offset from the first rotation axis about the rotation axis.

In addition to one or more of the features described above, or as an alternative, further examples of the system may include that the first pyrometer has a first pyrometer field of view at radially outer peripheral surface portion of the substrate, and that the second pyrometer has a second pyrometer field of view at a radially inner surface portion of the substrate. The second pyrometer field of view may have a width that is greater than a width of the first pyrometer field of view.

In addition to one or more of the features described above, or as an alternative, further examples of the system may include that the second pyrometer is radially offset from the rotation axis by between about 5 millimeters and about 130 millimeters. The second pyrometer may have a second pyrometer field of view with a width that is between about 10 millimeter and about 30 millimeters at the surface of the substrate.

In addition to one or more of the features described above, or as an alternative, further examples of the system may include that the instructions further cause the controller to acquire a plurality of first temperature measurements from the first pyrometer during rotation of the substrate about the rotation axis and acquire a plurality of second temperature measurements from the second pyrometer during rotation of the substrate about the rotation axis.

In addition to one or more of the features described above, or as an alternative, further examples of the system may include that the instructions further cause the controller to calculate a first temperature average using the plurality of first temperature measurements and calculate a second temperature average using the plurality of second temperature measurements. An inter-pyrometer average temperature difference may be determined between the first temperature average and the second temperature average and the inter-pyrometer average temperature difference compared to a predetermined inter-pyrometer average temperature differential value to determine substrate decentering.

In addition to one or more of the features described above, or as an alternative, further examples of the system may include that the instructions cause the controller to calculate a first temperature standard deviation using the plurality of first temperature measurements, calculate a second temperature standard deviation using the plurality of second temperature measurements, and determine a standard deviation difference between the first temperature standard deviation and the second temperature standard deviation. The calculated standard deviation difference may be compared to a predetermined inter-pyrometer standard deviation differential value to determine the substrate decentering.

In addition to one or more of the features described above, or as an alternative, further examples of the system may include that the instructions cause the controller to calculate a first amplitude of temperature measurement oscillation at a frequency twice a rotational speed of the substrate support using the plurality of first temperature measurements, calculate a second amplitude of temperature measurement oscillation at a frequency twice the rotational speed of the substrate support using the plurality of second temperature measurements, and determine an inter-pyrometer temperature oscillation difference between the first amplitude of temperature measurement oscillation and the second amplitude of temperature measurement oscillation. The determined inter-pyrometer temperature oscillation difference may be compared to a predetermined inter-pyrometer temperature oscillation differential value to determine substrate decentering.

A material layer deposition method is provided. The method includes, at a semiconductor processing system as described above, seating a substrate on the substrate support and acquiring a temperature measurement acquired using electromagnetic radiation emitted by the substrate. Decentering of the substrate relative to the rotation axis is determined using the electromagnetic radiation received at the pyrometer.

In addition to one or more of the features described above, or as an alternative, further examples of the method may include rotating the substrate support about the rotation axis, acquiring a first temperature measurement using electromagnetic radiation emitted by the substrate at a first rotary position, and acquiring a second temperature measurement using electromagnetic radiation emitted by the substrate at a second rotary position. Determining decentering of the substrate may include calculating a difference between the first temperature measurement and a second temperature measurement and comparing the calculated difference to a predetermined temperature difference value.

In addition to one or more of the features described above, or as an alternative, further examples of the method may include acquiring a plurality of temperature measurements using electromagnetic radiation emitted by the substrate during rotation about the rotation axis. Determining decentering of the substrate may include calculating a standard deviation of the plurality of temperature measurements and comparing the standard deviation to a predetermined temperature standard deviation value.

In addition to one or more of the features described above, or as an alternative, further examples of the method may include acquiring a plurality of temperature measurements using electromagnetic radiation emitted by the substrate during rotation about the rotation axis. Determining substrate decentering may include determining amplitude of temperature measurement oscillation at a frequency twice a rotational speed of the substrate support and comparing the determined amplitude of temperature measurement oscillation to a predetermined temperature measurement oscillation value.

In addition to one or more of the features described above, or as an alternative, further examples of the method may include that the pyrometer is a first pyrometer and that the semiconductor processing system further comprises a second pyrometer radially offset from the first pyrometer. The material layer deposition method may further include further include acquiring a plurality of first temperature measurements from the first pyrometer during rotation of the substrate about the rotation axis and acquiring a plurality of second temperature measurements from the second pyrometer during rotation of the substrate about the rotation axis.

In addition to one or more of the features described above, or as an alternative, further examples of the method may include calculating a first temperature average using the plurality of first temperature measurements and calculating a second temperature average using the plurality of second temperature measurements. An inter-pyrometer average temperature difference between the first temperature average and the second temperature average may be determined and the inter-pyrometer average temperature difference compared to a predetermined inter-pyrometer average temperature differential value to determine decentering of the substrate relative to the rotation axis.

In addition to one or more of the features described above, or as an alternative, further examples of the method may include calculating a first temperature standard deviation using the plurality of first temperature measurements and calculating a second temperature standard deviation using the plurality of second temperature measurements. A standard deviation difference between the first temperature standard deviation and the second temperature standard deviation may be determined and the determined standard deviation difference compared to a predetermined inter-pyrometer standard deviation differential value to determine decentering of the substrate relative to the rotation axis.

In addition to one or more of the features described above, or as an alternative, further examples of the method may include calculating a first amplitude of temperature measurement oscillation at a frequency twice a rotational speed of the substrate support using the plurality of first temperature measurements and calculating a second amplitude of temperature measurement oscillation at a frequency twice the rotational speed of the substrate support using the plurality of second temperature measurements. An an inter-pyrometer temperature oscillation difference between the first amplitude of temperature measurement oscillation and the second amplitude of temperature measurement oscillation may be determined and the determined inter-pyrometer temperature oscillation difference compared to a predetermined inter-pyrometer temperature oscillation differential value to determine decentering of the substrate relative to the rotation axis.

A computer program product is provided. The computer program product includes a non-transitory machine-readable medium having a plurality of program modules recorded on the medium that, when read by a controller, cause the controller to seat a substrate on a substrate support operably associated with the controller, the substrate support arranged within an interior of a chamber body and supported for rotation about a rotation axis; acquire a temperature measurement with a pyrometer disposed in communication with the controller, the pyrometer supported above the chamber body using electromagnetic radiation emitted by the substrate, the pyrometer radially offset from the rotation axis and optically coupled to the interior of the chamber body; and determine decentering of the substrate relative to the rotation axis using the electromagnetic radiation received by the pyrometer.

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a schematic diagram of a semiconductor processing system in accordance with the present disclosure, showing a material layer being deposited onto a substrate supported within a chamber arrangement during rotation of the substrate and the substrate support about a rotation axis within the chamber arrangement;

FIG. 2 is a cross-sectional side view of the chamber arrangement of FIG. 1 according to an example of the present disclosure, showing a substrate centered on a substrate support with a material layer deposited onto the substrate;

FIG. 3 is a plan view of the substrate and the substrate support of FIG. 1 according to an example of the present disclosure, showing the substrate having a concentric seating and thereby centered relative to the rotation axis while seated on the substrate support;

FIG. 4 is a plan view of substrate and the substrate support of FIG. 1 according to an example of the present disclosure, showing the substrate seated on the substrate support with an eccentric seating when the substrate and the substrate support are in a first rotary position;

FIG. 5 is a plan view of substrate and the substrate support of FIG. 1 according to an example of the present disclosure, showing the substrate seated on the substrate support with the eccentric seating when the substrate and the substrate support are in a second rotary position;

FIG. 6 is a cross-sectional side view of the chamber arrangement of FIG. 1, showing the substrate support dislocated due to lift pin binding that was incipiently indicated by substrate decentering on the substrate support relative to the rotation axis of the substrate support;

FIG. 7 is a graph of intensity of electromagnetic radiation emitted by substrates seated on the substrate support of FIG. 1 during rotation of the substrate and substrate support about a rotation axis according to an example of the present disclosure, comparatively showing variation in intensity of electromagnetic radiation received at a pyrometer from a decentered substrate relative to variation in intensity of electromagnetic radiation received at the pyrometer from a centered substrate, respectively; and

FIGS. 8-12 are a block diagram of a material layer deposition method according to the present disclosure, showing operations of the method according to an illustrative and non-limiting example of the method.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

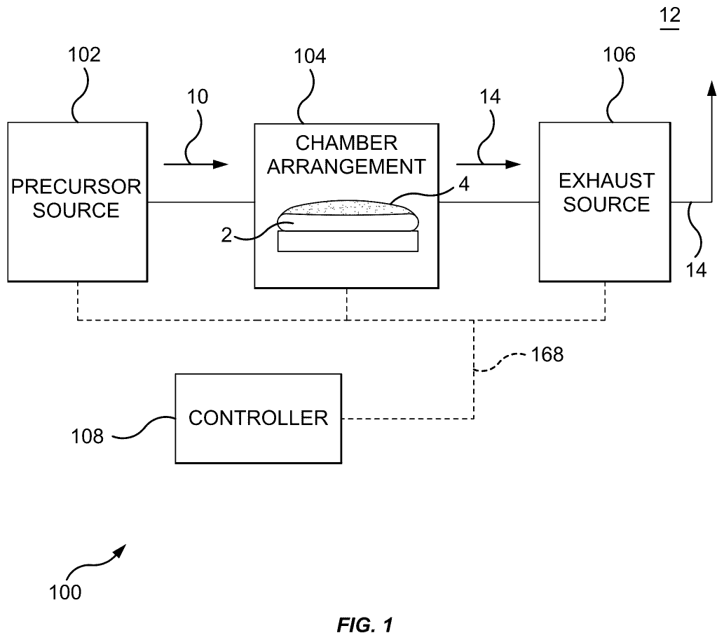

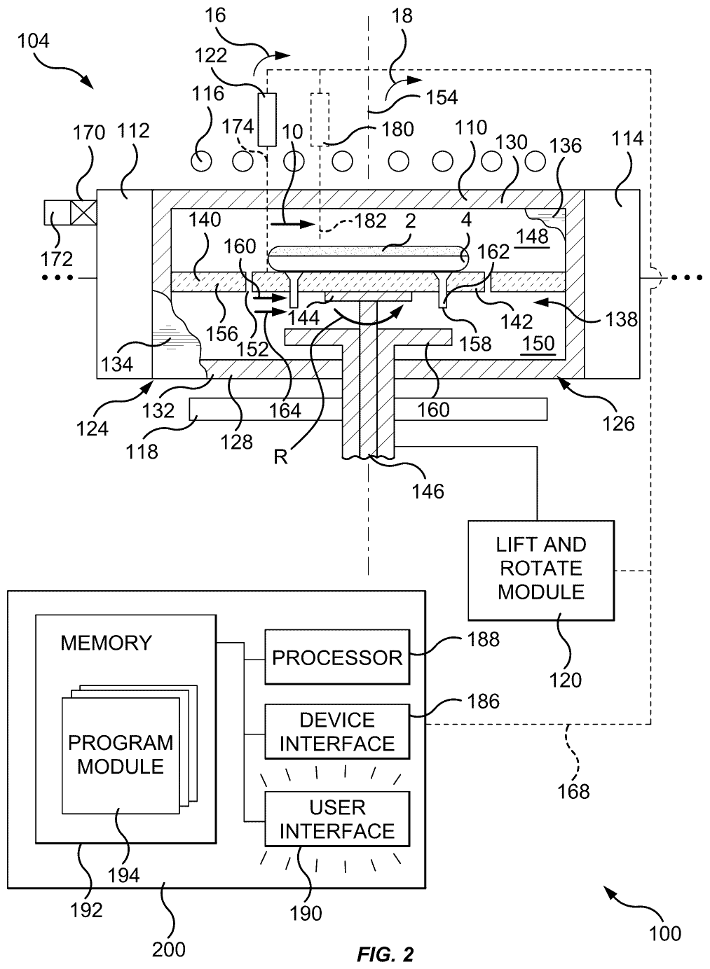

Reference will now be made to the drawings wherein like references numerals identify similar structural features or aspects of the subject disclosure. For purposes of explanation and illustration, and not limitation, a partial view of an example of a semiconductor processing system in accordance with the present disclosure is shown in FIG. 1, and is designated generally by reference character 100. Other examples of semiconductor processing systems, methods of determining decentering of a substrate, and methods of forming structures on substrates in accordance with the present disclosure, or aspects thereof, are provided in FIGS. 2-12, as will be described. The systems and methods of the present disclosure may be used to determine decentering of a substrate on a substrate support during deposition of a material layer onto the substrate, for example during deposition of silicon-containing material layers onto substrates using epitaxial techniques in single wafer crossflow chamber arrangements, though present disclosure is not limited to any particular type of deposition technique or chamber arrangement in general.

Referring to FIG. 1, the semiconductor processing system 100 is shown. The semiconductor processing system 100 generally includes a precursor source 102, a chamber arrangement 104, an exhaust source 106, and a controller 108. The precursor source 102 is configured to provide a flow of a material layer precursor 10 to the chamber arrangement 104. The chamber arrangement 104 is connected to the precursor source 102 and configured to deposit a material layer 4 onto a substrate 2 seated within the chamber arrangement 104. The exhaust source 106 is connected to the chamber arrangement 104, is fluidly coupled to an external environment 12 outside of the semiconductor processing system 100, and is configured to communicate a flow residual precursor and/or reaction products 14 to an external environment 12 outside of the semiconductor processing system 100. The controller 108 is operatively connected to the semiconductor processing system 100 to control deposition of the material layer 4 onto the substrate 2 using the flow of the material layer precursor 10 provided to the chamber arrangement 104 by the precursor source 102.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes, for example a 300-millimeter wafer. Substrates may be made from semiconductor materials, including, for example, silicon (Si), silicon germanium (SiGe), silicon oxide (SiO₂), gallium arsenide (GaAs), gallium nitride (GaN) and silicon carbide (SiC). As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

With reference to FIG. 2, the chamber arrangement 104 is shown according to an example. In the illustrated example the chamber arrangement 104 includes a chamber body 110, an injection flange 112, and an exhaust flange 114. As shown and described herein the chamber arrangement 104 also includes an upper heater element array 116, a lower heater element array 118, a lift and rotate module 120, and a pyrometer 122. Although shown and described herein as including certain elements and having a specific arrangement, e.g., a single-substrate crossflow arrangement, it is to be understood and appreciated that the chamber arrangement 104 include other elements and/or exclude certain elements shown and described herein, or have a different arrangement, and remain within the scope of the present disclosure.

The chamber body 110 extends between an injection end 124 and a longitudinally opposite exhaust end 126. The injection flange 112 abuts the injection end 124 of the chamber body 110 and couples the precursor source 102 (shown in FIG. 1) to the chamber body 110. The exhaust flange 114 abuts the exhaust end 126 of the chamber body 110 and couples the chamber body 110 to the exhaust source 106 (shown in FIG. 1). It is contemplated that the chamber body 110 be formed from a transparent material 128. It is also contemplated that the chamber body 110 have an upper wall 130, a lower wall 132, a first sidewall 134, and a second sidewall 136. The upper wall 130 of the chamber body 110 extends between the injection flange 112 and the exhaust flange 114, and may be substantially planar in shape. The lower wall 132 of the chamber body 110 is similar to the upper wall 130 of the chamber body 110 and is additionally spaced apart from the upper wall 130 by the interior 138 of the chamber body 110. The first sidewall 134 and second sidewall 136 are spaced apart from one another by an interior 138 of the chamber body 110, and couple the upper wall 130 to the lower wall 132. In certain examples, the transparent material 128 may include a ceramic material, such as quartz or sapphire by way of non-limiting example. In accordance with certain examples, the chamber body 110 may have a plurality of external ribs extending laterally about an exterior of the chamber body 110 and longitudinally spaced apart from one another between the injection end 124 and the exhaust end 126 of the chamber body 110. It is also contemplated that the upper wall 130 and/or the lower wall 132 may define an arcuate profile and/or have a dome-like shape and remain within the scope of the present disclosure.

The upper heater element array 116 is supported above the upper wall 130 of the chamber body 110 and is configured to radiantly heat the substrate 2 by transmitting electromagnetic radiation, e.g., electromagnetic radiation within an infrared waveband, through the transparent material 128 forming the upper wall 130 of the chamber body 110. In this respect the upper heater element array 116 may include a plurality of filament-type linear lamps extending laterally across the upper wall 130 of the chamber body 110 and longitudinally spaced apart from one another between injection end 124 and the exhaust end 126 of the chamber body 110. The lower heater element array 118 is similar to the upper heater element array 116, is supported below the lower wall 132 of the chamber body 110, and may also include a plurality of filament-type linear lamps extending longitudinally between the injection end 124 and the exhaust end 126 of the chamber body 110 and laterally spaced apart from one another. It is also contemplated that either (or both) the upper heater element array 116 and the lower heater element array 118 may alternatively (or additionally) include a plurality of bulb-type lamps and remain within the scope of the present disclosure.

As shown and described herein the chamber arrangement 104 also includes a divider 140, a substrate support 142, a support member 144, and a shaft member 146. The divider 140 is fixed within the interior 138 of the chamber body 110, divides the interior 138 of the chamber body 110 into an upper chamber 148 and a lower chamber 150, and defines a divider aperture 152 therethrough. The substrate support 142 is arranged within the interior 138 of the chamber body 110 and at least partially in the divider aperture 152, and is supported for rotation R within the interior 138 of the chamber body 110 about a rotation axis 154. The support member 144 is arranged within the lower chamber 150 of the chamber body 110 and along the rotation axis 154, and is fixed in rotation relative to the substrate support 142. The shaft member 146 is in turn fixed in rotation relative to the support member 144, extends along the rotation axis 154 and through the lower wall 132 of the chamber body 110, and operably couples the lift and rotate module 120 to the substrate support 142 for rotation R of the of the substrate support 142 about the rotation axis 154. In certain examples either (or both) the divider 140 and the substrate support 142 may be formed from an opaque material 156, e.g., a material opaque to the electromagnetic radiation generated by the upper heater element array 116 and the lower heater element array 118, such as a material opaque to electromagnetic radiation within an infrared waveband. Examples of suitable opaque materials include silicon carbide, graphite, and pyrolytic carbon. In accordance with certain examples, either or both the support member 144 and the shaft member 146 may be formed from a transparent material, such as the transparent material 128.

As also shown and described herein the chamber arrangement 104 further includes a plurality of lift pins 158 and a lift pin actuator 160. The plurality of lift pins 158 are slidable received with lift pin apertures 162 defines within the substrate support 142 and are movable between a first position 164, wherein the plurality of lift pins 158 are recessed within the substrate support 142 and dangle within the lower chamber 150 of the chamber body 110 to seat the substrate 2 on to the substrate support 142, and a second position 166, wherein the plurality of lift pins 158 protrude from the substrate support 142 into the upper chamber 148 to unseat the substrate 2 from the substrate support 142. It is contemplated that movement of the plurality of lift pins 158 be accomplished by operation of the lift pin actuator 160, which extends about the shaft member 146 within the lower chamber 150 of the chamber body 110, and which is operably associated with the lift and rotate module 120 for translation along the rotation axis 154 to drive the plurality of lift pins 158 between the first position 164 and the second position 166. It is also contemplated that the lift and rotate module 120 be operably associated with the controller 108, for example through a wired or wireless link 168, to seat the substrate 2 on the substrate support 142 prior to the deposition of the material layer 4 onto the substrate 2 and unseat the substrate 2 from the substrate support 142 subsequent to deposition of the material layer 4 onto the substrate 2. It is contemplated that seating and unseating of the substrate 2 be in cooperation with a gate valve 170 and a substrate transfer robot 172 with an end effector configured to carry the substrate 2.

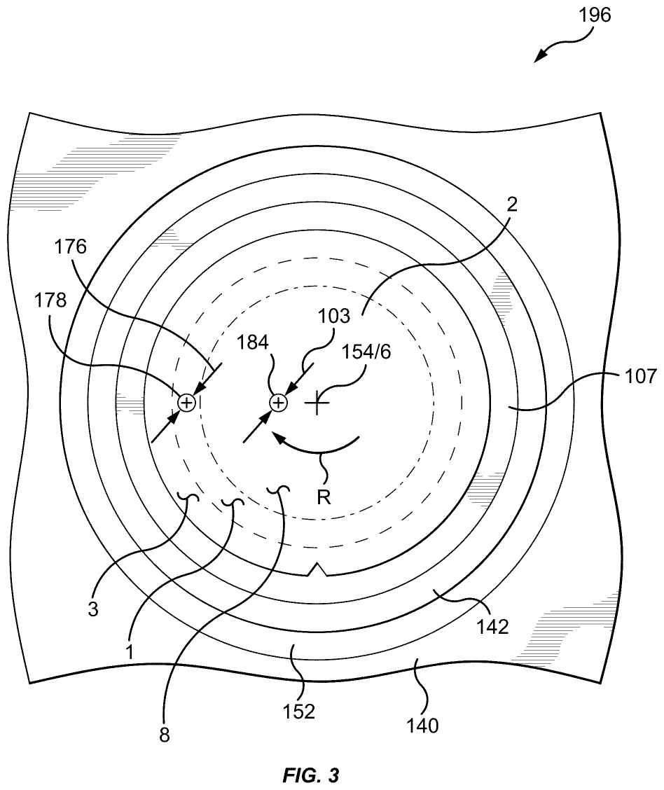

The pyrometer 122 is supported above the upper wall 130 of the chamber body 110, overlays the substrate support 142, and is optically coupled to the interior 138 of the chamber body 110 by an optical axis 174. The optical axis 174 may be substantially parallel to the rotation axis 154. The optical axis 174 may be further radially offset from the rotation axis 154 such that, when the substrate 2 has a concentric seating 196 (shown in FIG. 3), the optical axis 174 intersects a radially outer peripheral surface portion 1 of the substrate 2 located radially between a radially inner interior surface portion 8 and a bevel surface portion 5 of the substrate 2. It is further contemplated that the pyrometer 122 have a field of view 178 (shown in FIG. 3) at the radially outer peripheral surface portion 1 of the substrate 2 from within which the pyrometer 122 receives electromagnetic radiation emitted by the substrate 2. The field of view 178 may extend about optical axis 174, be radially offset from the rotation axis 154 by between about 130 millimeters and about 145 millimeters, and have a width 176 that is between about 2 millimeters and about 10 millimeters. As will be appreciated by those of skill in the art view of the present disclosure, field of view widths within this range may cooperate with optical axis offsets within these ranges to limit the effect that temperature gradient within the radially outer peripheral surface portion 1 of the substrate 2 may have on temperature measurements acquired by the pyrometer 122. Limiting temperature gradient with the field of view 178 of the pyrometer 122 in turn improves accuracy of temperature measurements acquired by the pyrometer 122 and thereby temperature control of the substrate 2 during deposition of the material layer 4 onto the substrate 2 using electromagnetic radiation emitted by the substrate 2 and received at the pyrometer 122 during rotation R of the substrate 2 and the substrate support 142 about the rotation axis 154.

It is contemplated that the pyrometer 122 may be a first pyrometer 122 and the chamber arrangement 104 may include one or more second pyrometer 180. The one or more second pyrometer 180 may be similar to the first pyrometer 122 and additionally supported above the upper wall 130 of the chamber body 110 at a location radially between the rotation axis 154 and the first pyrometer 122. The one or more second pyrometer 180 may be further arranged along a second pyrometer optical axis 182 and have a second pyrometer field of view 184 (shown in FIG. 3) at the radially inner interior surface portion 8 of the substrate 2. The second pyrometer optical axis 182 may be parallel to the first optical axis 174. The second pyrometer optical axis 182 may be radially between the first optical axis 174 and the rotation axis 154, and may be circumferentially offset from the first optical axis 174 about the rotation axis 154. The second pyrometer field of view 184 may be larger than the first pyrometer field of view 178 at the surface of the substrate 2, and in this respect may have a width 103 that is greater than the width 176 of the first pyrometer field of view 178. It is contemplated that the one or more second pyrometer 180 be configured to provide a second temperature measurement 18 to the controller 108 acquired using electromagnetic radiation emitted from the radially inner interior surface portion 8 of the substrate 2 occupying the second pyrometer field of view 184. In certain examples, the second pyrometer 180 (e.g., the second pyrometer optical axis 182) may be radially offset from the rotation axis 154 by between about 5 millimeters and about 130 millimeters. In accordance with certain examples, the width 103 of the second pyrometer field of view 184 may between about 10 millimeters and about 30 millimeters at the radially inner interior surface portion 8 of the substrate 2.

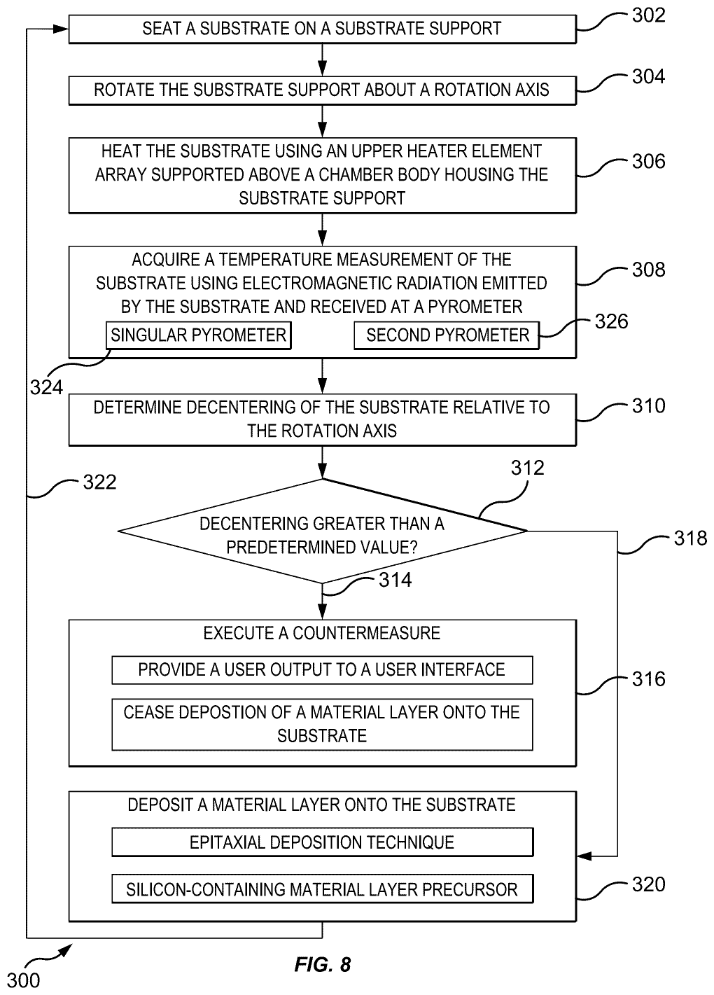

The controller 108 includes a device interface 186, a processor 188, a user interface 190, and a memory 192. The device interface 186 couples the processor 188 to the wired or wireless link 168. The processor 188 is operably connected to the user interface 190, for example to receive user input from user through the user interface 190 and provide user output to the user through the user interface 190, and is disposed in communication with the memory 192. The memory 192 includes a non-transitory machine-readable medium having a plurality of program modules 194 recorded thereon that, when read by the processor 188, cause the processor 188 to execute certain operations and in this respect may be a computer program 200. Among the operations are operations of a material layer deposition method 300 (shown in FIG. 8), as will be described. Although shown and described herein as having a specific architecture it is to be understood and appreciated that the controller 108 may have a different architecture in other examples of the present disclosure, e.g., a distributed computing architecture, and remain within the scope of the present disclosure.

Deposition of the material layer 4 may be accomplished within the chamber arrangement 104 by opening the gate valve 170 and advancing an end effector carrying the substrate 2 into the interior 138 of the chamber body 110 using the substrate transfer robot 172. Typically, the substrate transfer robot 172 advances the end effector longitudinally within the upper chamber 148 of the chamber body 110 toward the exhaust end 126 of the chamber body 110 such that the substrate 2 is registered to the substrate support 142 at a location above the substrate support 142. Once the substrate 2 is registered to the substrate support 142 the lift and rotate module 120 translates the lift pin actuator 160 upward within the lower chamber 150 of the chamber body 110 along the rotation axis 154, the lift pin actuator 160 in turn driving the plurality of lift pins 158 upwards through the substrate support 142 between the first position 164 and the second position 166 (shown in FIG. 3), the substrate 2 transferring from the substrate transfer robot 172 as the plurality of lift pins 158 reach the second position 166. Once the substrate 2 is transferred to the plurality of lift pins 158 the substrate transfer robot 172 withdraws the end effector from the chamber body 110 and the gate valve 170 closed. The lift and rotate module 120 may then translate the lift pin actuator 160 downwards within the lower chamber 150 along the rotation axis 154, downward translation of the lift pin actuator 160 causing the plurality of lift pins 158 to slide downward within the plurality of lift pin apertures 162 by operation of gravity upon the substrate 2 and the plurality of lift pins 158. As the plurality of lift pins 158 slide downwards through the substrate support 142 between the second position 166 and the first position 164 the substrate 2 seats on the substrate support 142, further sliding movement of the plurality of lift pins 158 leaving tips of the plurality of lift pins 158 seated within a pocket of the substrate support 142 and stems of the plurality of lift pins 158 dangling within the lower chamber 150 of the chamber body 110.

The substrate support 142 and the substrate 2 may be rotated about the rotation axis 154, the substrate 2 heated using radiant heat generated by the upper heater element array 116 and the lower heater element array 118, and the substrate 2 exposed to the material layer precursor 10 under environmental conditions that cause the material layer 4 to deposit onto the substrate 2. Once deposition is complete rotation of the substrate 2 and the substrate support 142 ceases and the plurality of lift pins 158 again moved between the first position 164 and the second position 166 such that substrate 2 with the material layer 4 deposited thereon may be removed from the chamber body 110 in cooperation with the gate valve 170 and the substrate transfer robot 172.

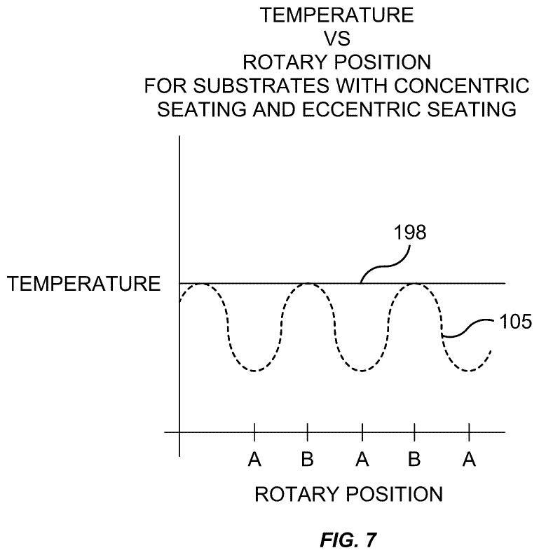

With reference to FIG. 3, seating the substrate 2 typically results in placement of the substrate 2 on the substrate support 142 with a concentric seating 196. When concentrically seated the rotation axis 154 of the chamber arrangement 104 intersects a substrate center 6 of the substrate 2, a radially inner interior surface portion 8 of the substrate 2 extending about the substrate center 6 occupies the second pyrometer field of view 184, a radially outer peripheral surface portion 1 of the substrate 2 extending about the radially inner interior surface portion 8 of the substrate 2 occupies the first pyrometer field of view 178, and the substrate 2 contacts the substrate support 142 at a bevel 3 extending circumferentially about the radially outer peripheral surface portion 1 of the such that a bevel surface portion 5 of the substrate 2 is radially outward of first pyrometer field of view 178. Advantageously, seating the substrate 2 with the concentric seating 196 enables controlling temperature of the substrate 2 with relatively good accuracy using electromagnetic radiation emitted by the substrate 2 within the first field of view 178 of the first pyrometer 122 as the bevel surface portion 5 of the substrate 2 remains radially outward of the first field of view 178 of the first pyrometer 122 during rotation R of the substrate 2 and the substrate support 142 about the rotation axis 154, as shown with concentric seating temperature trace 198 (shown in FIG. 7). In certain examples, the bevel 3 may be about 150 millimeters offset from the substrate center 6. In accordance with certain examples, the bevel surface portion 5 may have a radial width that is between about 1 millimeter and about 5 millimeters. It is contemplated that, in certain examples, the radially outer peripheral surface portion 1 may have a radial width that is between about 4 and about 30 millimeters. It is also contemplated that, in accordance with certain examples, the radially inner interior surface portion 8 may have a radial with that is between about 120 millimeters and about 145 millimeters.

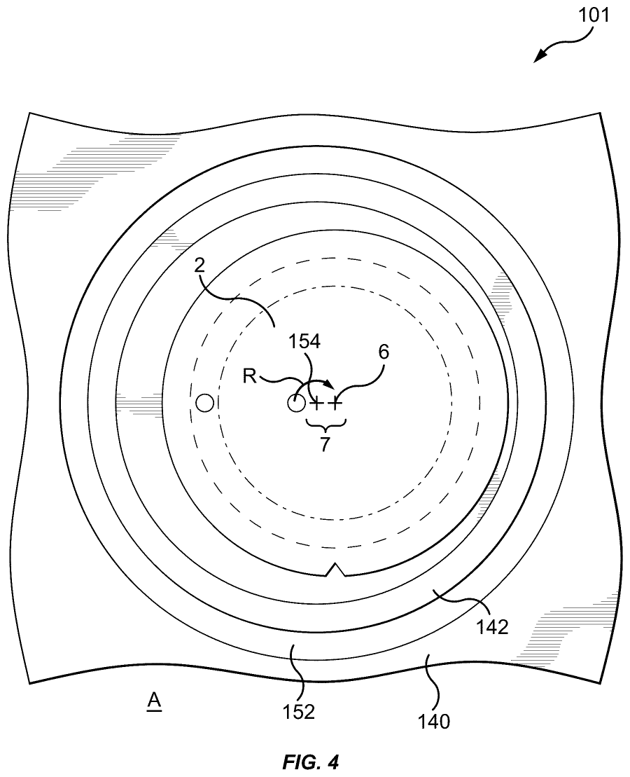

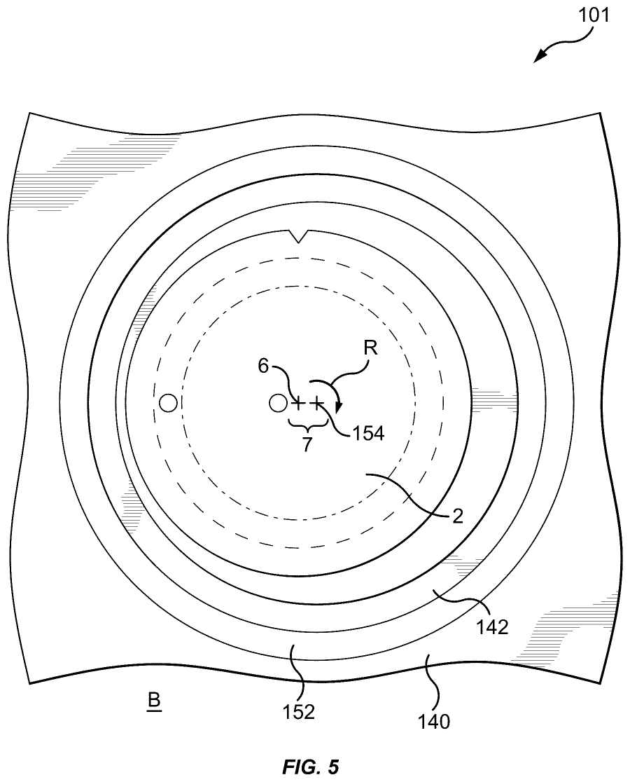

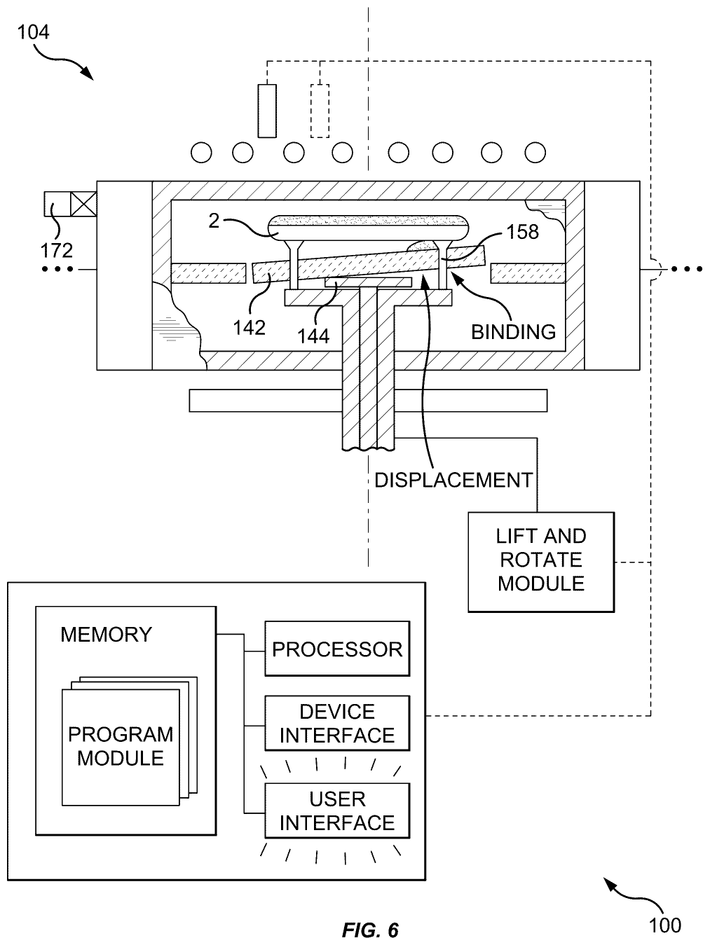

As will be appreciated by those of skill in the art in view of the present disclosure, and as shown in FIGS. 4 and 5, conditions may develop within the chamber arrangement 104 (shown in FIG. 2) that cause the substrate 2 to adopt an eccentric seating 101 on the substrate support 142 wherein the substrate center 6 is radially offset from the rotation axis 154 by a decentering distance 7. For example, service and/or replacement of the substrate transfer robot 172 (shown in FIG. 2) included in the chamber arrangement 104 (shown in FIG. 2) may alter position of the substrate 2 at transfer between the end effector and the plurality of lift pins 158 (shown in FIG. 2) slidably received within the substrate support 142, potentially cause the substrate 2 to seat eccentrically on the substrate support 142. Material may accrete within the lift pin apertures 162 (shown in FIG. 2) defined within the substrate support 142 and/or on the plurality of lift pins 158 received within the plurality of lift pin apertures 162. The accreted material can, in some deposition operations, cause one or more of the plurality of lift pins 158 to slide obliquely through the substrate 2 relative to the rotation axis 154, also potentially causing the substrate 2 to seat eccentrically on the substrate support 142. And, if not appreciated and addressed, accretion may develop within the chamber arrangement 104 sufficient to cause one of more of the lift pins 158 to bind within the substrate support 142, as shown in FIG. 6, potentially causing the substrate 2 to seat eccentrically on the substrate support 142 due to displacement of the substrate support 142 from the support member 144 due to the lift pin binding and/or bringing risk of damage to structures within the interior 138 of the chamber arrangement 104 during processing of further substrates within the chamber arrangement 104.

As will also be appreciated by those of skill in the art in view of the present disclosure, eccentric seating 101 of the substrate 2 on the substrate support 142 influences the variation in temperature measurements acquired by the pyrometer 122. Without being bound by a particular theory or mode of operation, it is believed that temperature differential at between the bevel 3 and the radially inner interior surface portion 8 of the substrate 2 causes temperature measurements acquired by the pyrometer 122 to vary according to an eccentric seating temperature trace 105 during rotation R of the substrate 2 and the substrate support 142 about the rotation axis 154. This is because the eccentric seating 101 causes the bevel surface portion 5 of the substrate 2 to intrude into (and thereby at least partially occupy) the field of view 178 when the substrate support 142 is in a first rotary position A (shown in FIG. 4) about the rotation axis 154, and retreat from (and thereby no longer occupy) the field of view 178 when the substrate support 142 is in a second rotary position B. Advantageously, such as in substrates exhibiting center-to-edge temperature differential due contact between the substrate 2 and the substrate support 142 about a ledge 107 (shown in FIG. 3) of the substrate support 142, variation introduced into real-time temperature measurements acquired using the pyrometer 122 with periodicity corresponding to rotational frequency (speed) of the substrate support 142 may be employed to indicate substrate decentering. The indicated decentering may be acquired during heating of the substrate 2, such as prior to deposition of the material layer 4, and employed to determine whether decentering is such that processing need be interrupted and/or appreciate incipient risk of pin binding due to accretion accumulation within the chamber arrangement 104.

With reference to FIGS. 8-12, the material layer deposition method 300 is shown according to an illustrative and non-limiting example of the method. As shown in FIG. 8, the method 300 generally includes seating a substrate on a substrate support, e.g., the substrate 2 (shown in FIG. 1) on the substrate support 142 (shown in FIG. 1) and rotating the substrate and the substrate support about a rotation axis, e.g., the rotation axis 154 (shown in FIG. 2), as shown with box 302 and box 304. The method 300 also includes heating the substrate using an upper heater element array supported above a chamber body, e.g., the upper heater element array 116 (shown in FIG. 2) supported above the chamber body 110 (shown in FIG. 2) housing the substrate support, and acquiring a temperature measurement of the substrate with a pyrometer, e.g., the temperature measurement 16 (shown in FIG. 2) acquired using the pyrometer 122 (shown in FIG. 2) supported above the chamber body using electromagnetic radiation emitted by the substrate, as shown with box 306 and box 308. It is contemplated that the method 300 further include determining decentering of the substrate relative to the rotation axis, as shown with box 310 and box 312, executing a countermeasure when the determined decentering is greater than a predetermined decentering value, as shown with arrow 314 and box 316, and continuing processing by depositing a material layer onto the substrate when the determined decentering is less than the predetermined decentering value, as shown with arrow 318 and box 320. The method 300 may continue during sequential material layer deposition operations, for example during sequential deposition of material layer on singular substrates in chamber arrangements having single-wafer crossflow architectures, as shown with arrow 322.

Seating 302 the substrate may include opening a gate valve and advancing an end effector into the chamber body using a substrate transfer robot, e.g., the gate valve 170 (shown in FIG. 2) and the substrate transfer robot 172 (shown in FIG. 2), as also shown with box 302. Seating the substrate may include driving a plurality of lift pins slidably received within the substrate support through the substrate support using a lift pin actuator, e.g., the plurality of lift pins 158 (shown in FIG. 2) using the lift pin actuator 160 (shown in FIG. 2), as further shown with box 302. Seating 302 the substrate on the substrate support may include retracting the lift pin actuator such that the plurality of lift pins retract into the substrate support by operation of gravity upon the plurality of lift pins and the substrate, as additionally shown with box 302.

Rotating 304 the substrate and the substrate support about the rotating axis may include rotating a shaft member and a support member fixed in rotation relative to the substrate support about the rotation axis, e.g., the shaft member 146 (shown in FIG. 2) and the support member 144 (shown in FIG. 2), as also shown with box 304. Rotating 304 the substrate and the substrate support may include eccentrically rotating the substrate about the rotation axis, for example when a substrate center of the substrate is radially offset from the rotation axis, as further shown with box 304. Rotating 304 the substrate and the substrate support about the rotation axis may include rotating the substrate support eccentrically about the rotation axis, for example when the substrate has been displaced from the support member and/or according to wobble and runout of the substrate support, such as may result from lift pin binding and/or service of the chamber arrangement, as additionally shown with box 304.

Heating 306 the substrate may include communicating radiant heat into the chamber arrangement using the upper heater element array and/or a lower heater element array, e.g., the lower heater element array 118 (shown in FIG. 2), as also shown with box 306. Heating 306 the substrate may include heating the substrate while rotating the substrate about the rotation axis, as further shown with box 306. Heating 306 the substrate may include ramping temperature to a predetermined material layer deposition temperature prior to exposing the substrate to a material layer precursor employed to subsequently deposit a material layer onto the substrate, e.g., the material layer precursor 10 (shown in FIG. 1), as additionally shown with box 306.

Acquiring 308 the temperature measurement may include using electromagnetic radiation emitted by the substrate received at the pyrometer along an optical axis substantially parallel to the rotation axis, e.g., the optical axis 174 (shown in FIG. 2), as also shown with box 308. Acquiring 308 the temperature measurement may include receiving the electromagnetic radiation along an optical axis that is between about 130 millimeters and about 150 millimeters from the rotation axis, for example between about 135 millimeters and about 150 millimeters, or between about 140 millimeters and about 150 millimeters, or even between about 140 millimeters and about 145 millimeters from the rotation axis, as further shown with box 308. Acquiring 308 the temperature measurement may include acquiring the temperature measurement from a field of view at the substrate surface that is between about 2 millimeters wide and about 10 millimeters, or between about 4 millimeters wide and about 10 millimeters wide, or even that is between about 4 millimeters wide and about 8 millimeters wide, as additionally shown with box 308.

In certain examples, acquiring 308 the temperature measurement may include using electromagnetic radiation emitted by a peripheral surface portion of the substrate, e.g., the radially outer peripheral surface portion 1 (shown in FIG. 3), during rotation of the substrate and the substrate support about the rotation axis. In this respect it is contemplated that the peripheral surface portion of the substrate may fully occupy the field of view of the pyrometer during rotation of the substrate during rotation of the substrate and the substrate support about the rotation axis, such as when decentering of substrate is relatively small (e.g., within a millimeter of the substrate center being coaxial with the rotation axis). In accordance with certain examples, acquiring 308 the temperature measurement may include using electromagnetic radiation emitted by a bevel surface portion of the substrate, e.g., the bevel surface portion 5 (shown in FIG. 3), during rotation of the substrate and the substrate support about the rotation axis. In this respect it is contemplated that the bevel surface portion of the substrate may at least partially occupy the field of view of the pyrometer during rotation of the substrate during rotation of the substrate and the substrate support about the rotation axis, such as when decentering of substrate is relatively large (e.g., the substrate center radially offset from the rotation axis by more than 1 millimeter). It is also contemplated that the decentering may be such that the bevel surface portion enter and retreat from the field of the view of the pyrometer during rotation of the substrate and the substrate support about the rotation axis, and that emissivity differences between the interior surface portion of the substrate and the bevel surface portion of the substrate throttle temperature measurements (e.g., introduce variation in to the temperature measurements) acquired by the pyrometer.

In certain examples the pyrometer may be a singular pyrometer, i.e., a chamber arrangement configured to control substrate temperature with a singular pyrometer, as shown with box 324. In accordance with certain examples, temperature measurements may be acquired using a first pyrometer and a second pyrometer, e.g., the second pyrometer 180 (shown in FIG. 2), as shown with box 326. In such examples the second pyrometer may be radially inward first pyrometer, for example radially between the rotation axis and the first pyrometer, as further shown with box 326. In such examples the second pyrometer may have a second pyrometer field of view that is larger than the first pyrometer, e.g., the second pyrometer field of view 184 (shown in FIG. 3), which may be smaller than the first pyrometer field of view, as also shown with box 326. For example, the second pyrometer field of view width may be between about 10 and 30 millimeters at the substrate surface, for example between about 10 millimeters and about 30 millimeters, or between about 15 millimeters and about 25 millimeters, or even between about 15 millimeters and about 20 millimeters.

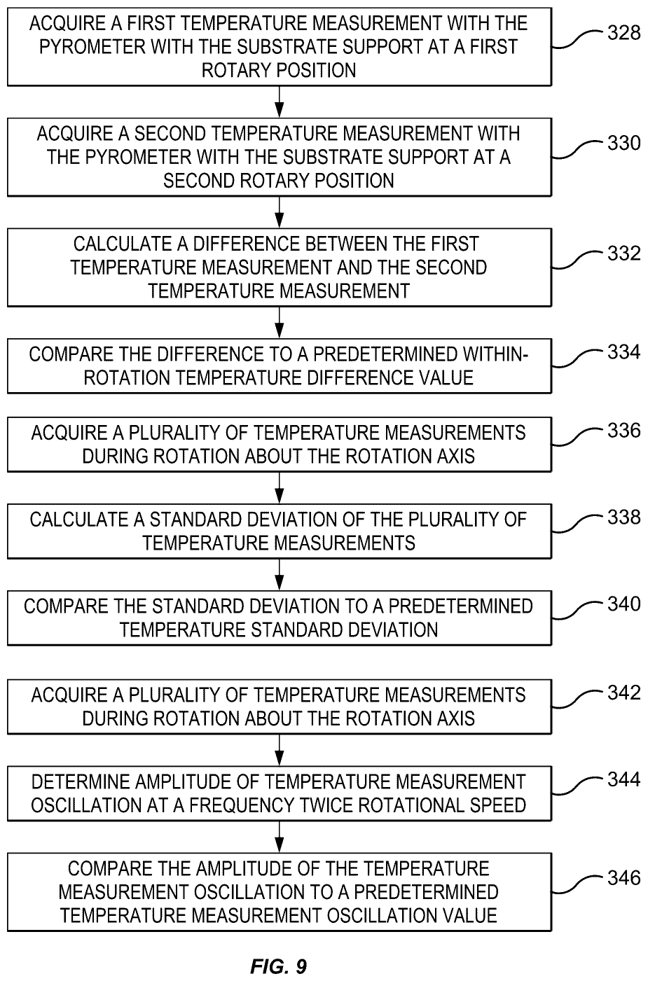

As shown in FIG. 9, determining 310 decentering may include acquiring a first temperature measurement using the pyrometer with the substrate support in a first rotary position, e.g., the first rotary position A (shown in FIG. 4), and acquiring a second temperature measurement using the pyrometer with the substrate support in a second rotary position, e.g., the second rotary position B (shown in FIG. 5), as shown with box 302 and box 304. A difference between the first temperature measurement and the second temperature measurement may be determined, as shown with box 306, and the difference compared to a predetermined within-rotation temperature difference value, such as a predetermined within-rotation temperature difference value recorded in one of the plurality of program modules 194 (shown in FIG. 2) recorded on the memory 192 (shown in FIG. 2), as shown with box 308. The substrate may be determined to be decentered when the calculated temperature difference is greater than the predetermined within-rotation temperature difference, as shown with box 360 (shown in FIG. 8).

In certain examples, determining 350 decentering of the substrate relative to the rotation axis may include acquiring a plurality of temperature measurements from the substrate during rotation of the substrate and the substrate support about the rotation axis, e.g., 30 or more temperature measurements acquired in real-time rotation during a single rotation about the rotation axis, as shown with box 302. A standard deviation may be calculated using the plurality of temperature measurements, as shown with box 304, and the calculated standard deviation compared to a predetermined standard deviation value, as shown with box 306. The substrate may be determined to be decentered when the calculated standard deviation is greater than the predetermined standard deviation value, and the predetermined standard deviation may be recorded in one or the plurality of program modules recorded on the memory, as shown with box 360 (shown in FIG. 8).

In accordance with certain examples, determining 350 decentering of the substrate relative to the rotation axis may include acquiring a plurality of temperature measurements during two or rotations of the substrate support about the rotation axis, as shown with box 300. Amplitude of temperature measurement oscillation at twice a frequency of the rotational speed (e.g., rotational frequency of the substrate support) may be determined using the determined amplitude of temperature measurement oscillation during rotation about the rotation axis, as shown with box 300, the amplitude compared to a predetermined temperature measurement oscillation value, as shown with box 300. The predetermined temperature measurement oscillation value may be recorded in one of the program modules recorded on the memory, and the substrate may be determined to be decentered when the determined amplitude of temperature measurement oscillation during rotation about the rotation axis is greater than the predetermined oscillation value, as shown with box 360 (shown in FIG. 8).

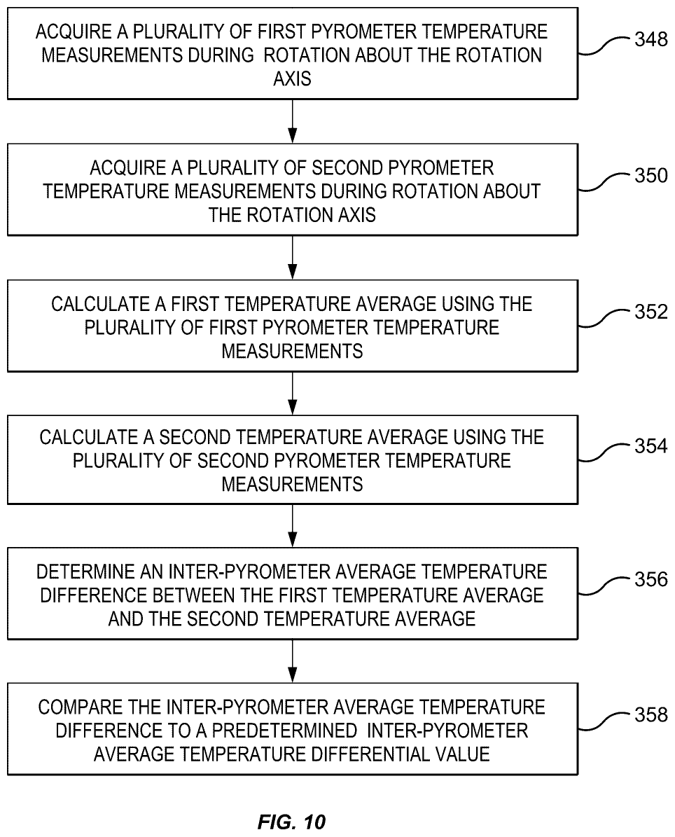

As shown in FIG. 10, determining 350 decentering of the substrate relative to the rotation axis may include acquiring a plurality of first pyrometer temperature measurements from the first pyrometer and acquiring a plurality of second pyrometer temperature measurements from the second pyrometer during rotation of the substrate and the substrate support about the rotation axis, as shown with box 300 and with box 300. A first temperature measurement average may be calculated using the plurality of first pyrometer temperature measurements and a second temperature measurement average may be calculated using the plurality of second pyrometer temperature measurements, as shown with box 300 and with box 300, and an inter-pyrometer average temperature difference determined between the first temperature measurement average and the second pyrometer temperature measurement average, as shown with box 300. The inter-pyrometer average temperature difference may be compared to a predetermined inter-pyrometer average temperature differential value, as shown with box 300. The predetermined inter-pyrometer average temperature differential value may be recorded in one of the plurality of program modules recorded on the memory, and the substrate may be determined to be decentered when the inter-pyrometer average temperature difference is greater than the predetermined inter-pyrometer average temperature differential value, as shown with box 360 (shown in FIG. 8).

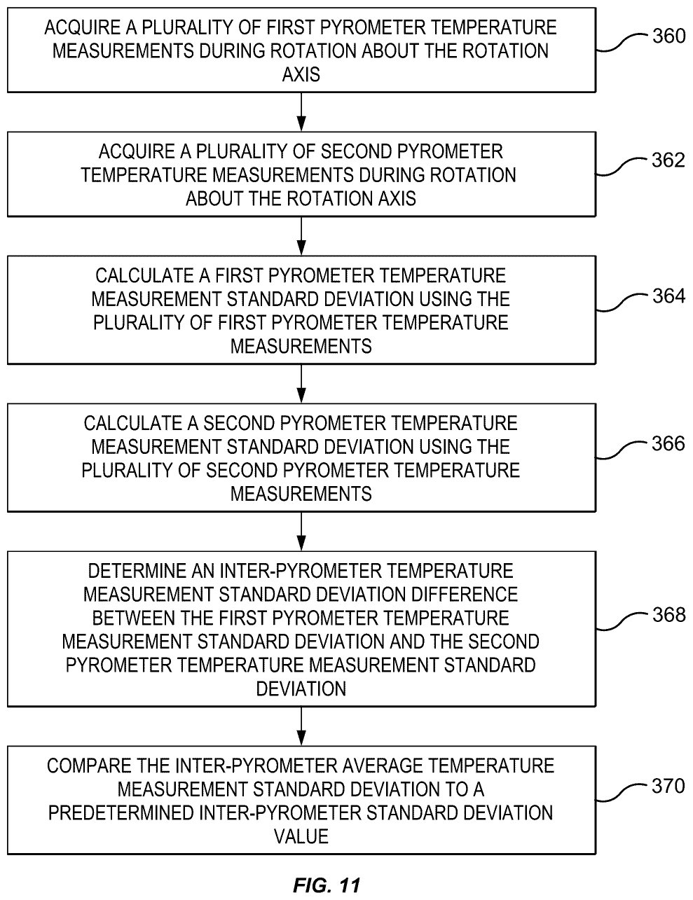

As shown in FIG. 11, determining 310 decentering of the substrate relative to the rotation axis may include acquiring a plurality of first pyrometer temperature measurements from the first pyrometer and acquiring a plurality of second pyrometer temperature measurements from the second pyrometer during rotation of the substrate and the substrate support about the rotation axis, as shown with box 360 and box 362. A first pyrometer temperature measurement standard deviation may be calculated using the plurality of first pyrometer temperature measurements and a second pyrometer temperature measurement standard deviation may be calculated using the plurality of second pyrometer temperature measurements, as shown with box 364 and with box 366, and an inter-pyrometer temperature measurement standard deviation difference determined between the first pyrometer temperature measurement standard deviation and the second pyrometer temperature measurement standard deviation, as shown with box 368. The inter-pyrometer temperature measurement standard deviation difference may be compared to a predetermined inter-pyrometer temperature measurement standard deviation differential value, as shown with box 300. The predetermined inter-pyrometer temperature measurement standard deviation differential value may be recorded in one of the plurality of program modules recorded on the memory, and the substrate may be determined to be decentered when the inter-pyrometer temperature measurement standard deviation difference is greater than the predetermined inter-pyrometer temperature measurement standard deviation differential value, as further shown with box 360 (shown in FIG. 8).

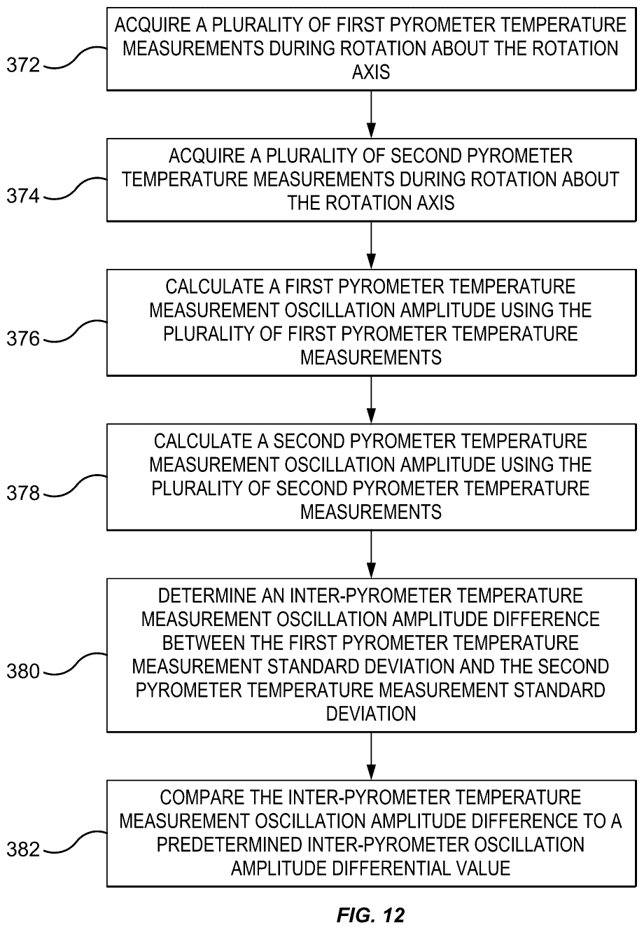

As shown in FIG. 12, determining 310 decentering of the substrate relative to the rotation axis may, in certain examples, include comparing amplitude of temperature measurement oscillation in temperature measurements acquired by both the first pyrometer and the second pyrometer. In this respect a plurality of first pyrometer temperature measurements may be acquired using the first pyrometer and a plurality of second pyrometer temperature measurements acquired using the second pyrometer, as shown with box 372 and box 374. A first pyrometer temperature measurement oscillation amplitude may be calculated using the plurality of first pyrometer temperature measurements and a second pyrometer temperature measurement oscillation amplitude calculated using the plurality of second pyrometer temperature measurements, as shown with box 376 and box 378. It is contemplated that an inter-pyrometer temperature measurement oscillation difference be calculated between the first pyrometer temperature measurement oscillation amplitude and the second pyrometer temperature measurement oscillation amplitude, and the inter-pyrometer temperature measurement oscillation amplitude difference compared to a predetermined inter-pyrometer oscillation amplitude differential value, as shown with box 380 and box 382. The predetermined inter-pyrometer oscillation amplitude differential value may be recorded in one of the plurality of program modules recorded on the memory, and the substrate may be determined to be decentered when the inter-pyrometer temperature measurement oscillation differential is greater than the predetermined inter-pyrometer oscillation amplitude differential value, as additionally shown with box 360 (shown in FIG. 8).

With continuing reference to FIG. 8, executing 316 a countermeasure may include providing a user output to a user interface, e.g., a user output to the user interface 190 (shown in FIG. 2), as shown with box 384. Executing 316 a countermeasure may include interrupting operation of the semiconductor processing system, for example ceasing deposition of the material layer onto the substrate seated on the substrate support within the chamber arrangement, as shown with box 386. It is also contemplated that the one or more of the aforementioned predetermined may be graduated, smaller determined decentering resulting user outputs while processing continues, and larger determined decentering also resulting in user outputs and ceasing deposition of the material layer onto the substrate. As will be appreciated by those of skill in the art in view of the present disclosure, this enable a user to balance throughput against variation in a way appropriate to the semiconductor device being fabricated using the material layer deposited onto the substrate seated on the substrate support.

Depositing 320 the material layer onto the substrate may include depositing the substrate using an epitaxial deposition technique, e.g., such that material layer has an epitaxial structure relative to a crystalline structure of the underlying substrate, as shown with box 386. Depositing 320 the material layer may include depositing the material layer using a silicon-containing material layer precursor, as shown with box 388. Depositing 320 the material layer may include depositing the material layer using an alloying constituent-containing material layer precursor and/or a dopant-containing material layer precursor, as also shown with box 320. Examples of suitable alloying constituent-containing material layer precursors include germanium-contain material layer precursors. Examples of suitable dopant-containing material layer precursors include n-type dopant-containing material layer precursors and p-type dopant-containing material layer precursors.

Deposition of material layers onto a substrate may be accomplished by seating a substrate on a substrate support within a chamber arrangement of a semiconductor processing system, heating the substrate to a predetermined material layer deposition temperature, and exposing the substrate to a material layer precursor under environmental conditions selected to cause a material layer to deposit onto the substrate. Once deposition of the material layer is complete the substrate may be unseated from the substrate support, removed from the chamber arrangement and the semiconductor processing system and sent on to undergo further processing, as appropriate for the material layer being deposited on the substrate. Deposition may be accomplished by rotating the substrate and the substrate support within the chamber arrangement about a rotation axis, temperature control of the substrate may be accomplished using one or more pyrometers supported outside of the chamber arrangement and seating and unseating of the substrate from the substrate support accomplished using lift pins slidably received within the lift pin apertures defined within the substrate support.

In some semiconductor processing systems conditions may come to exist that cause the substrate to be decentered on the substrate support relative to the rotation axis. For example, the substrate transfer robot employed to position the substrate on the lift pins may change placement of the substrate on the lifts, such as due to service and/or replacement of the substrate transfer robot. Material may accrete on the lift pins and/or within the lift pin apertures within which the lift pins are slidable received, potentially causing one or more of the lift pins to move in a direction oblique relative to the rotation axis and decentering the substrate upon seating on the substrate support. And the substrate support may itself rotate eccentrically relative to the rotation axis, such as due to wobble induced by displacement of the substrate support within the chamber arrangement, such as in the unlikely event that one or more of the lift pins binds during sliding movement through the substrate support. As will be appreciated by those of skill in the art in view of the present disclosure, substrate decentering can change properties of the material layer deposited onto the substrate, for example by increasing cross-substrate material layer thickness variation. Substrate decentering may also impact reliability of the semiconductor processing system employed for material layer deposition, for example when the decentering is indicative of an incipient problem such as material accretion sufficient to interrupt processing and/or cause damage to structures within the chamber arrangement employed for material layer deposition.

In examples described herein temperature information provided by the pyrometers is employed to determine decentering of the substrate. In certain examples, variation in temperature measurements acquired by a pyrometer radially offset from the rotation axis is used to determine whether the substrate is rotating eccentrically relative to the rotation, for example due a bevel surface portion of the substrate entering and existing a field of view of the pyrometer with a periodicity corresponding to rotational speed of the substrate support about the rotation axis. Advantageously, frequency analysis of real-time temperature information provided by the pyrometer may provide indication of substrate de-centering prior to material layer deposition, such as during temperature ramping prior to deposition of the material layer onto the substrate, limiting (or eliminating) risk that substrate decentering lead to rework or scrapping of the substrate due to influence of the decentering on the material layer deposited onto the substrate.

In accordance with certain examples, decentering may be determined using temperature differential exhibited during rotation, standard deviation of temperature measurements acquired during rotation, and/or amplitude in temperature measurement oscillation during rotation of the substrate and substrate support about the rotation axis. Advantageously, this can increase sensitivity to relatively small amounts of decentering, such as in substrates having relatively high center-to-edge temperature differentials like patterned substrates with high emissivity, temperature difference between the bevel surface portion and the peripheral surface portion tending to inflate temperature standard deviation in a way that corresponds to the magnitude of decentering exhibited by a given substrate. It is also contemplated that, in accordance with certain examples, decentering may be determined using one or more second pyrometer supported outside of the chamber arrangement at a location radially between the rotation axis and the first (or radially-outer) pyrometer. Advantageously, temperature measurements acquired using the one or more second pyrometer may exhibit less variation due to substrate decentering, temperature measurements acquired by the second pyrometer thereby improving accuracy of the decentering determination made using temperature measurements acquired using the first pyrometer, for example by distinguishing between variation in temperature measurements acquired by the first pyrometer attributable to noise versus due to substrate decentering.

Although this disclosure has been provided in the context of certain embodiments and examples, it will be understood by those skilled in the art that the disclosure extends beyond the specifically described embodiments to other alternative embodiments and/or uses of the embodiments and obvious modifications and equivalents thereof. In addition, while several variations of the embodiments of the disclosure have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure should not be limited by the particular embodiments described above.

The subject matter of the present disclosure includes all novel and nonobvious combinations and subcombinations of the various processes, systems, and configurations, and other features, functions, acts, and/or properties disclosed herein, as well as any and all equivalents thereof. The headings provided herein, if any, are for convenience only and do not necessarily affect the scope or meaning of the devices and methods disclosed herein.

1. A semiconductor processing system, comprising:
a chamber body;
a substrate support arranged within an interior of the chamber body and supported for rotation about a rotation axis;
a pyrometer supported above the chamber body, radially offset from the rotation axis, and optically coupled to the interior of the chamber body; and
a controller operably connected to the substrate support and disposed in communication with the pyrometer, the controller responsive to instructions recorded on a non-transitory machine-readable memory to:
seat a substrate on the substrate support;
acquire a temperature measurement acquired using electromagnetic radiation emitted by the substrate; and
determine decentering of the substrate relative to the rotation axis using the electromagnetic radiation received at the pyrometer.

2. The semiconductor processing system of claim 1, wherein the pyrometer is radially offset from the rotation axis by between about 135 millimeters and about 150 millimeters, and wherein the pyrometer has a field of view with a width that is between about 2 millimeter and about 10 millimeters.

3. The semiconductor processing system of claim 1, wherein the substrate has a radially outer bevel surface portion and a radially outer peripheral surface portion, wherein the rotation axis intersects the interior surface portion of the substrate, wherein the peripheral surface portion extends about the interior surface portion of the substrate, and wherein the bevel surface portion extends circumferentially about the peripheral surface portion of the substrate.

4. The semiconductor processing system of claim 1, wherein the instructions cause the controller:
rotate the substrate support about the rotation axis;
acquire a first temperature measurement using the electromagnetic radiation emitted by the substrate at a first rotary position;
acquire a second temperature measurement using electromagnetic radiation emitted by the substrate at a second rotary position;
calculate a difference between the first temperature measurement and the second temperature measurement; and
compare the calculated difference to a predetermined temperature difference value.

5. The semiconductor processing system of claim 1, wherein the instructions cause the controller to:
acquire a plurality of temperature measurements using the electromagnetic radiation emitted by the substrate during rotation about the rotation axis;
calculate a standard deviation of the plurality of temperature measurements; and
compare the calculated standard deviation to a predetermined temperature standard deviation value.

6. The semiconductor processing system of claim 1, wherein the instructions cause the controller to:
acquire a plurality of temperature measurements using the electromagnetic radiation emitted by the substrate during rotation about the rotation axis;
determine amplitude of temperature measurement oscillation at a frequency twice a rotational speed of the substrate support; and
compare the determined amplitude of temperature measurement oscillation to a predetermined temperature measurement oscillation value.

7. The semiconductor processing system of claim 1, wherein the pyrometer is a first pyrometer and the semiconductor processing system further comprises one or more second pyrometer, the one or more second pyrometer supported above the chamber body and radially inward of the first pyrometer.

8. The semiconductor processing system of claim 7, wherein the instructions further cause the controller to:
acquire a plurality of first temperature measurements from the first pyrometer during rotation of the substrate about the rotation axis; and
acquire a plurality of second temperature measurements from the one or more second pyrometer during rotation of the substrate about the rotation axis.

9. The semiconductor processing system of claim 8, wherein the instructions further cause the controller to:
calculate a first temperature average using the plurality of first temperature measurements;
calculate a second temperature average using the plurality of second temperature measurements;
determine an inter-pyrometer average temperature difference between the first temperature average and the second temperature average; and
compare the determined inter-pyrometer average temperature difference to a predetermined inter-pyrometer average temperature differential value.

10. The semiconductor processing system of claim 8, wherein the instructions further cause the controller to:
calculate a first temperature standard deviation using the plurality of first temperature measurements;
calculate a second temperature standard deviation using the plurality of second temperature measurements;
determine a standard deviation difference between the first temperature standard deviation and the second temperature standard deviation; and
compare the determined standard deviation difference to a predetermined inter-pyrometer standard deviation differential value.

11. The semiconductor processing system of claim 7, wherein the instructions further cause the controller to:
calculate a first amplitude of temperature measurement oscillation at a frequency twice a rotational speed of the substrate support using the plurality of first temperature measurements;
calculate a second amplitude of temperature measurement oscillation at a frequency twice the rotational speed of the substrate support using a plurality of second temperature measurements;
determine an inter-pyrometer temperature oscillation difference between the first amplitude of temperature measurement oscillation and the second amplitude of temperature measurement oscillation; and
compare the determined inter-pyrometer temperature oscillation difference to a predetermined inter-pyrometer temperature oscillation differential value.

12. A material layer deposition method, comprising:
at a semiconductor processing system including a chamber body, a substrate support arranged within an interior of the chamber body and supported for rotation about a rotation axis, a pyrometer supported above the chamber body that is radially offset from the rotation axis and optically coupled to the interior of the chamber body, and a controller operably connected to the substrate support and disposed in communication with the pyrometer,
seating a substrate on the substrate support;
acquiring a temperature measurement acquired using electromagnetic radiation emitted by the substrate; and
determining decentering of the substrate relative to the rotation axis using the electromagnetic radiation received at the pyrometer.

13. The material layer deposition method of claim 12, further comprising:
rotating the substrate support about the rotation axis;
acquiring a first temperature measurement using the electromagnetic radiation emitted by the substrate at a first rotary position;
acquiring a second temperature measurement using electromagnetic radiation emitted by the substrate at a second rotary position;
wherein determining decentering comprises (a) calculating a difference between the first temperature measurement and a second temperature measurement, and (b) comparing the calculated difference to a predetermined temperature difference value.

14. The material layer deposition method of claim 12, further comprising:
acquiring a plurality of temperature measurements using electromagnetic radiation emitted by the substrate during rotation about the rotation axis; and
wherein determining decentering comprises (a) calculating a standard deviation of the plurality of temperature measurements, and (b) comparing the calculated standard deviation to a predetermined temperature standard deviation value.

15. The material layer deposition method of claim 12, further comprising:
acquiring a plurality of temperature measurements using electromagnetic radiation emitted by the substrate during rotation about the rotation axis; and
wherein determining decentering comprises (a) determining amplitude of temperature measurement oscillation at a frequency twice a rotational speed of the substrate support, and (b) comparing the determined amplitude of temperature measurement oscillation to a predetermined temperature measurement oscillation value.

16. The material layer deposition method of claim 12, wherein the pyrometer is a first pyrometer and the semiconductor processing system further comprises a second pyrometer radially offset from the first pyrometer, the material layer deposition method further comprising:
acquiring a plurality of first temperature measurements from the first pyrometer during rotation of the substrate about the rotation axis; and
acquiring a plurality of second temperature measurements from the second pyrometer during rotation of the substrate about the rotation axis.

17. The material layer deposition method of claim 16, wherein determining decentering comprises:
calculating a first temperature average using the plurality of first temperature measurements;
calculating a second temperature average using the plurality of second temperature measurements;
determining an inter-pyrometer average temperature difference between the first temperature average and the second temperature average; and
comparing the determined inter-pyrometer average temperature difference to a predetermined inter-pyrometer average temperature differential value.

18. The material layer deposition method of claim 16, wherein determining decentering comprises:
calculating a first temperature standard deviation using the plurality of first temperature measurements;
calculating a second temperature standard deviation using the plurality of second temperature measurements;
determining a standard deviation difference between the first temperature standard deviation and the second temperature standard deviation; and
comparing the determined standard deviation difference to a predetermined inter-pyrometer standard deviation differential value.

19. The material layer deposition method of claim 16, wherein determining decentering comprises:
calculating a first amplitude of temperature measurement oscillation at a frequency twice a rotational speed of the substrate support using the plurality of first temperature measurements;
calculating a second amplitude of temperature measurement oscillation at a frequency twice the rotational speed of the substrate support using the plurality of second temperature measurements;
determining an inter-pyrometer temperature oscillation difference between the first amplitude of temperature measurement oscillation and the second amplitude of temperature measurement oscillation; and
comparing the determined inter-pyrometer temperature oscillation difference to a predetermined inter-pyrometer temperature oscillation differential value.

20. A computer program product, comprising:
a non-transitory machine-readable medium having a plurality of program modules recorded on the medium that, when read by a controller, cause the controller to:
seat a substrate on a substrate support operably associated with the controller, the substrate support arranged within an interior of a chamber body and supported for rotation about a rotation axis;
acquire a temperature measurement with a pyrometer disposed in communication with the controller, the pyrometer supported above the chamber body using electromagnetic radiation emitted by the substrate, the pyrometer radially offset from the rotation axis and optically coupled to the interior of the chamber body; and
determine decentering of the substrate relative to the rotation axis using the electromagnetic radiation received by the pyrometer.
